(19) United States
(12) Patent Application Publication
(10) Pub. No.: US 2008/0075302 A1
(43) Pub. Date: Mar. 27, 2008

(54) MULTIPLE AUDIO CHANNEL BASS MANAGEMENT METHOD AND SYSTEM

(75) Inventor: Hsing-Ju Wei, Kee-Lung City (TW)

Correspondence Address: THOMAS, KAYDEN, HORSTEMEYER & RISLEY, LLP, 600 GALLERIA PARKWAY, S.E., STE 1500, ATLANTA, GA, 30339-5994, US

(73) Assignee: MEDIATEK INC., Hsin-Chu (TW)

(21) Appl. No.: 11/530,950

(22) Filed: Sep. 12, 2006

(51) Int. Cl. H03G 5/00; H04R 5/00

(52) U.S. Cl. 381/99; 381/98; 381/17

(57) ABSTRACT

The invention provides a multiple audio channel bass management method for an audio system comprising multiple processing units, wherein each processing unit receives a corresponding channel signal and outputs to a speaker, the method comprising: high pass filtering a first channel signal to drive a first speaker and low pass filtering the first channel signal to generate a first low frequency signal if the first speaker is not a full range speaker; combining a first bass information signal and the first channel signal to drive the first speaker if the first speaker is a full range speaker, wherein the first bass information signal is derived from the low frequency signal generated by other processing unit.

### BACKGROUND OF THE INVENTION

1. Field of the Invention

The present invention relates to audio bass management, and more particularly to bass management method and system for multiple audio channels.

2. Description of the Related Art

The market demand for high quality audio supported consumer products has been fast expended. An audio decoder receives audio data from a signal source and converts into a decompressed form, and then the decompressed audio data is passed for further processing, such as filtering, summing, mixing and conversion into audio tones.

In addition, advanced audio decoders further perform post processing functions including bass management and 3D effects on dual-channel or multi-channel audio data. Bass management is employed when the bass component of a channel is capable of redirecting to another channel with a speaker that processes the entire frequency range. For example, Dolby Digital delivers five full range channels, Left, Right, Center, Left Surround and Right Surround, as well as one bass-only effects channel, Low Frequency Effect (LFE). The LFE carry additional bass information to supplement the bass information in the main channels. However, not every speaker has to cover the entire frequency range. For example, a small speaker has limited bass handling capabilities. Signals sent to small speakers will be high pass filtered to remove bass information. Audio systems have the flexibility to use speakers not processing low frequencies (for example, frequencies lower than 120 Hz) since the bass information can be redirected to and combined by a subwoofer. The combination of bass information in the subwoofer output is determined by the bass management settings chosen for the particular system's speakers.

FIG. 1 is a block diagram of a conventional bass management system. In FIG. 1, processing unit L 601a, processing unit R 601b, processing unit C 601c, processing unit Ls 601d and processing unit Rs 601e receive the LFE signal and the output signal, SUB, of the subwoofer summing module 602 to process and generate output signals, such as L′ and R′, to drive speakers. However, if the speaker driven by the processing unit is a small or high speaker, the processing path of LFE and SUB signals is redundant, thus, an appropriate multiple audio channel management method is desirable.

### BRIEF SUMMARY OF THE INVENTION

The invention provides an appropriate multiple audio channel bass management method capable of reducing the number of unnecessary processing paths.

The invention provides a multiple audio channel bass management method for an audio system comprising multiple processing units, wherein each processing unit receives a corresponding channel signal and outputs to a speaker, the method comprising: high pass filtering a first channel signal to drive a first speaker and low pass filtering the first channel signal to generate a first low frequency signal if the first speaker is not a full range speaker; combining a first bass information signal and the first channel signal to drive the first speaker if the first speaker is a full range speaker, wherein the first bass information signal is derived from the low frequency signal generated by other processing unit.

The invention provides an audio system with bass management, comprising a first processing unit and a second processing unit. The first processing unit high pass filters a first channel signal to drive a first speaker and low pass filters the first channel signal to generate a first low frequency signal if the first speaker is not a full range speaker, or combines a first bass information signal with the first channel signal to drive the first speaker if the first speaker is a full range speaker. The second processing unit selectively combines a second channel signal and the first low frequency signal to drive a second speaker, optionally redirects the second channel signal to the first processing unit as the first bass information if the first speaker is a full range speaker.

The invention provides a multi-speaker audio system comprising a first processing unit for driving a first speaker and a second processing unit for driving a second speaker. The first processing unit receiving one first audio channel signal comprises a first gain controller, a multiplexer, a low pass filter, a high pass filter and a summing module. The first gain controller adjusts the gain of the first audio channel signal. The multiplexer determines the processing path based on the type of the first speaker. The low pass filter generates a first low frequency signal based on the first audio channel signal. The high pass filter receives and processes the first audio channel signal to drive the first speaker when the first speaker is a small speaker. The summing module receives the first audio channel signal and a low frequency signal from at least one other channel to drive the first speaker when the first speaker is a large speaker. The second processing unit receiving a low frequency effect signal comprises a second gain controller, a first multiplexer, a second multiplexer and a summing module. The second gain controller adjusts the gain of the low frequency effect signal. The first multiplexer determines whether the low frequency effect signal is passing a low pass filter. The second multiplexer determines the processing path, wherein one processing path passes the signal combined with a signal from the summing module to the second speaker, and another processing path passes the signal to the first speaker when the first speaker is the large speaker. The summing module receives and sums the signal from the second multiplexer and first low frequency signal to drive the second speaker. In some embodiments, the first processing unit can process one of the left, right, left surround, right surround, or centre channel, whereas the second processing unit processes the LFE (low frequency effect) channel.

A detailed description is given in the following embodiments with reference to the accompanying drawings.

### BRIEF DESCRIPTION OF THE DRAWINGS

The present invention can be more fully understood by reading the subsequent detailed description and examples with references made to the accompanying drawings, wherein:

FIG. 1 is a block diagram of a conventional bass management system.

FIG. 2 is a block diagram showing an embodiment of an audio management processing unit of the invention.

FIG. 3 is a block diagram showing another embodiment of an audio management processing unit without driving a subwoofer.

FIG. 4 is a schematic diagram of an embodiment of the processing unit L 101

FIG. 5 is a schematic diagram of an embodiment of the subwoofer summing module 107.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

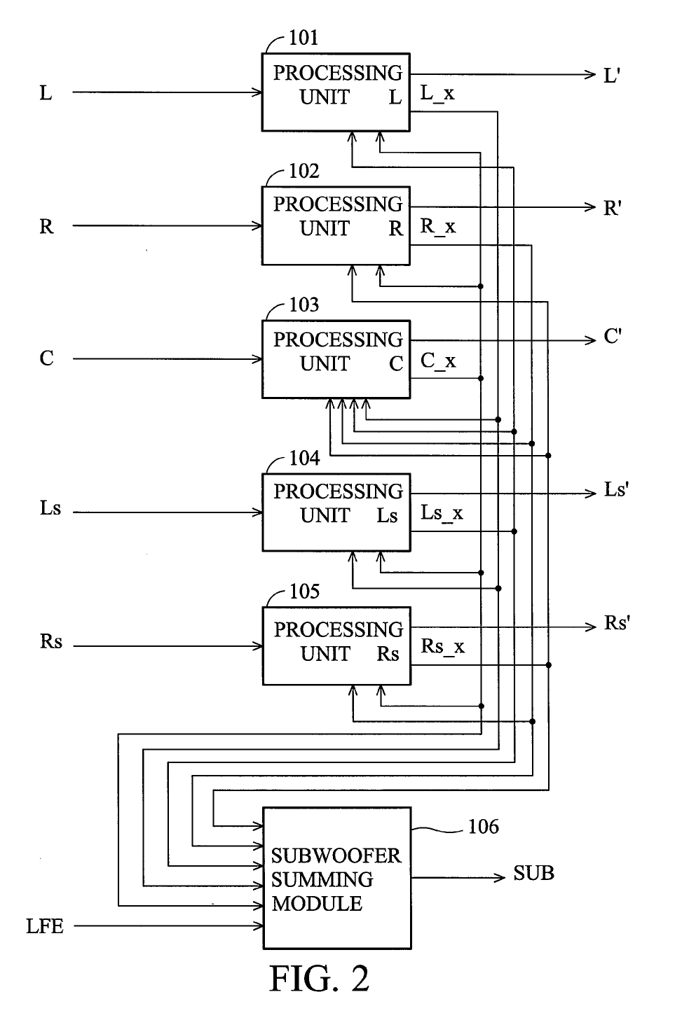

FIG. 2 is a block diagram of an embodiment of an audio bass management system. The audio bass management system 100 comprises a processing unit L (Left) 101, a processing unit R (Right) 102, a processing unit C (Center) 103, a processing unit Ls (Left surround) 104, a processing unit Rs (Right surround) 105, and a subwoofer summing module 106. The processing unit L 101 receives and processes an L channel audio data to generate an audio output L′ to drive a speaker, and it optionally generates a low frequency part L_x of the L channel audio data. The processing unit L 101 further optionally receives and processes low frequency parts Ls_x and C_x from the processing units Ls 104 and C 103 respectively if the speaker driven by audio output L′ is a large speaker. The processing unit L 101 can also drive a large speaker without summing the low frequency parts from other channels. In this embodiment, a larger speaker is a full range speaker capable of processing entire frequency range. Signals sent to a large speaker will be full bandwidth. Similarly, the processing unit R 102 may receive and process the low frequency parts Rs_x and C_x, the processing unit C 103 may receive and process the low frequency parts L_x, R_x, Ls_x and Rs_x, the processing unit Ls 104 may receive and process the low frequency parts L_x and C_x, and the processing unit Rs 105 may receive and process the low frequency parts R_x and C_x. The subwoofer summing module 106 receives a low frequency effect signal (LFE) and it optionally receives the low frequency parts of other channel audio data to generate a bass signal, SUB, to drive a woofer or a subwoofer. In an example, the subwoofer summing module 106 receives and processes at least one low frequency part from the five channels. In another example, the base signal SUB is determined only by the low frequency effect signal. When the speaker driven by a processing unit is a large speaker, the processing unit is capable of receiving and processing the low frequency parts from other channels.

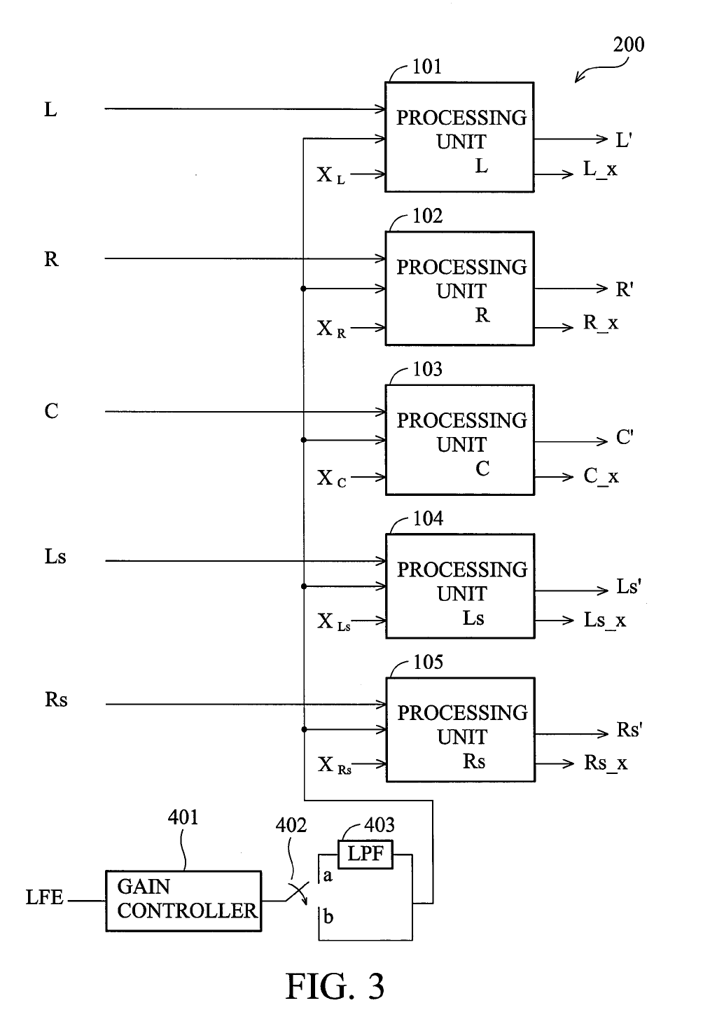

FIG. 3 is a block diagram of another embodiment of an audio base management system without driving a subwoofer. An LFE signal is passed through a gain controller 401 to adjust the gain of the LFE signal. The LFE signal may be filtered by a low pass filter 403 to reduce high frequency noises, and optionally sent to the processing unit 101˜105. The processing unit L 101 receives and processes an L channel audio data to generate an audio output L′ to drive a speaker, and it may also sum the LFE signal with the L channel audio data to produce the audio output L′ if driving a large speaker. Low frequency part X_{L} output from other channel (for example, one or a combination of the center channel and left surround channel) may also be summed with the L channel audio data to produce the audio output L′. X_{L} comprises at least one of the low frequency parts Ls_x and C_x. The processing unit L 101 may filter the L channel audio data to generate a low frequency part L_x and output to other processing unit, this is typically the case when the speaker is a small speaker. Similarly, the processing unit R 102, the processing unit C 103, the processing unit Ls 104, and the processing unit Rs 105 substantially operate the same as the processing unit L 101. The processing unit R 102 may receive a low frequency signal X_{R}, wherein the low frequency signal X_{R} comprises at least one of the low frequency parts Rs_x and C_x. The processing unit C 103 may receive a low frequency signal X_{Rs}, wherein the low frequency signal X_{Ls} comprises at least one of the low frequency parts L_x, R_x, Ls_x and Rs_x. The processing unit Ls 104 may receive a low frequency signal X_{Ls}, wherein the low frequency signal X_{Ls} comprises at least one of the low frequency parts L_x and C_x. The processing unit Rs 101 receive a low frequency signal X_{Rs}, wherein the low frequency signal X_{Rs} comprises at least one of the low frequency parts R_x and C_x. When the speaker driven by one of the processing units 101˜105 is a small speaker (high frequency speaker), the processing unit may block the low frequency parts from other channels and the LFE signal. When the speaker driven by one of the processing units 101˜105 is a large speaker, the processing unit is capable of receiving and processing the low frequency signal and LFE signal. Furthermore, even if the processing unit does not receive low frequency signals or the LFE signal, the output signal of the processing unit can still drive a large speaker.

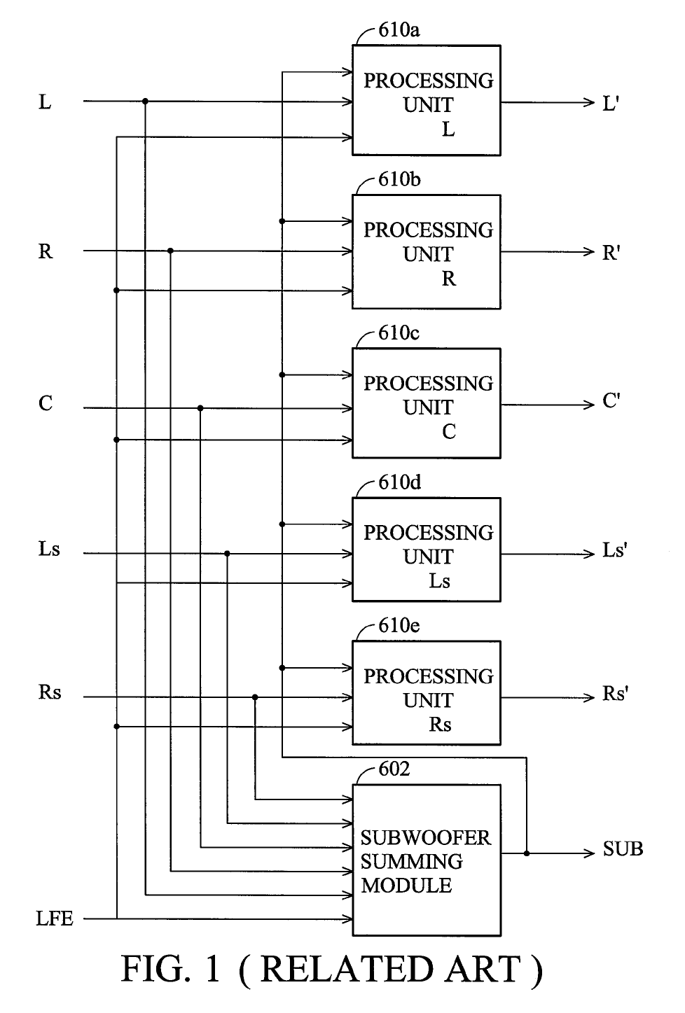

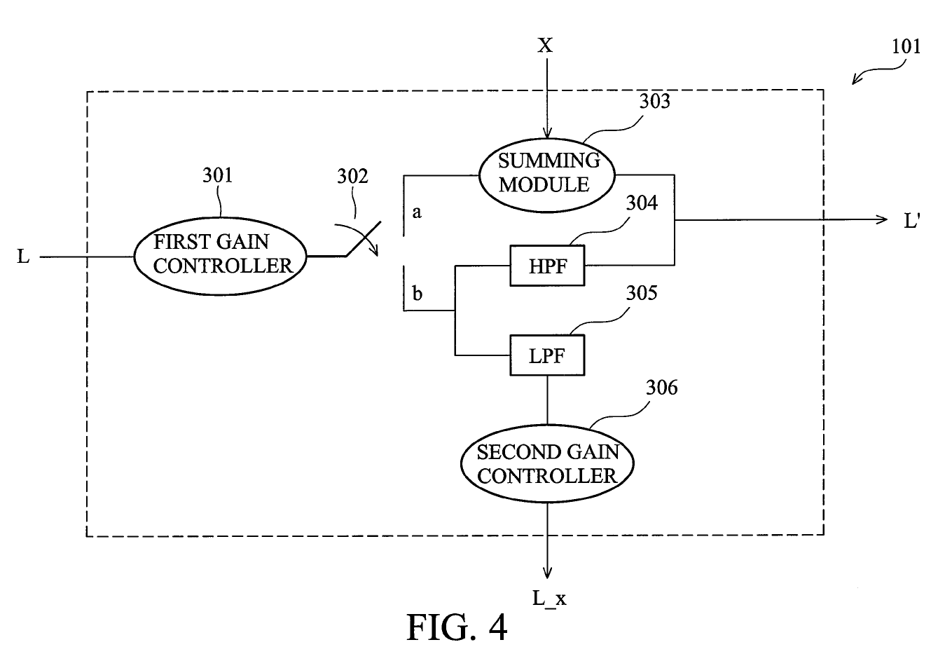

FIG. 4 is a schematic diagram of an embodiment of the processing unit L 101 of FIG. 1. The L channel audio data is input to a first gain controller 301 to adjust the level of L channel audio data. From the first gain controller 301, the L channel audio data can take either of the two paths, the first path a or the second path b, by the multiplexer 302. When the speaker driven by the L channel audio data is a large speaker, the first path a is taken. When the speaker driven by the L channel audio data is a large speaker, the second path b is taken. When the L channel audio data is processed through the first path b, the L channel audio data is combined at the summing module 303 with the low frequency signal X or the filtered LFE signal, such as the signal from the low pass filter 201. When the L channel audio data is processed through the second path b, the L channel audio data is passed through a high pass filter (HPF) 304 to drive the speaker and a low pass filter 305 to generate a low frequency part of the L channel audio data. The low frequency part of the L channel audio data is input to a second gain controller 306 to output the signal L_x.

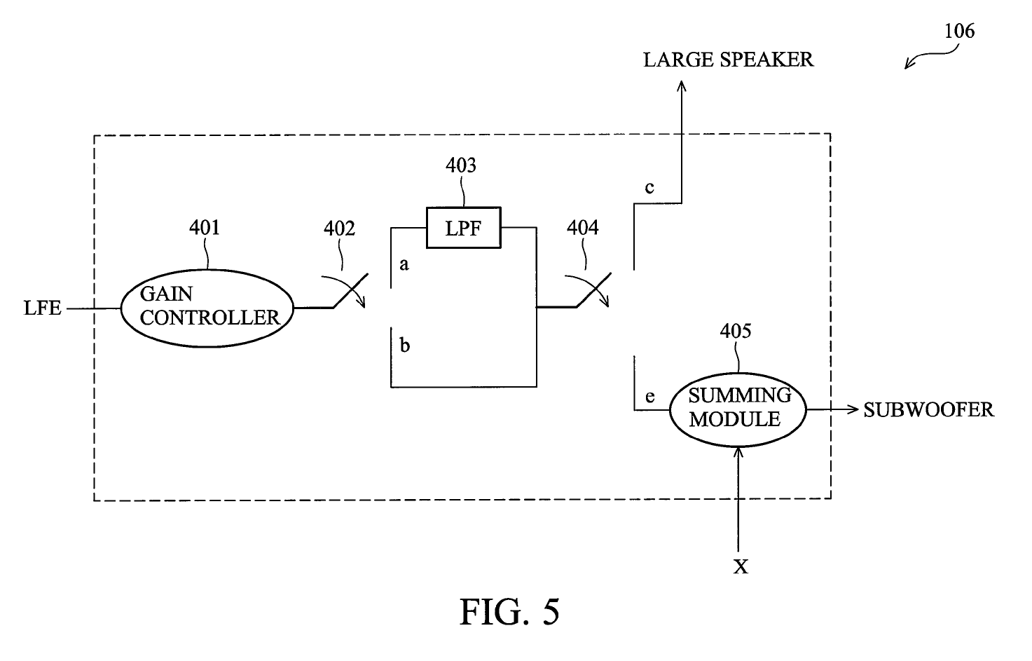

FIG. 5 is a schematic diagram of an embodiment of the subwoofer summing module 107 of FIG. 1. The LFE signal is input to a gain controller 401 to adjust the level of the LFE signal. From the gain controller 401, the LFE signal can take either of the two paths, the first path a and the second path b, by the first multiplexer 402. In the path a, the LFE signal is directed to a low pass filter 403 and in the path b, the LFE signal is directly directed to the second multiplexer 404. Then, the LFE signal can take one of the paths, the third path c or the fifth path e. When the subwoofer or the woofer does not supported, the path c is taken for directing the LFE signal to a large speaker. When the subwoofer or the woofer exits, the LFE signal can take the path e for directly directing the LFE signal to the subwoofer and/or take the path c for directing the LFE signal to a large speaker, i.e. When the LFE signal from the path a or path b is directing to the large speaker and subwoofer, the multiplexer 404 switches on the both the path c and the path e. In the path e, the LFE signal is combined at a summing module 405 with the low frequency signal X to drive the subwoofer or the woofer, wherein the low frequency signal X may be one of the low frequency parts of the five channel audio data, such as L_x. Moreover, signal from the summing module for driving the subwoofer can be directly directs to the subwoofer without the input low frequency signal X, i.e., the low frequency signal X is optional.

While the invention has been described by way of example and in terms of preferred embodiment, it is to be understood that the invention is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

1. A multiple audio channel bass management method for an audio system comprising multiple processing units, each processing unit receiving a corresponding channel signal and outputting to a speaker, the method comprising:
high pass filtering a first channel signal to drive a first speaker and low pass filtering the first channel signal to generate a first low frequency signal if the first speaker is not a full range speaker; and
combining a first bass information signal and the first channel signal to drive the first speaker if the first speaker is a full range speaker;
wherein the first bass information signal is derived from the low frequency signal generated by other processing unit.

2. The method as claimed in claim 1, wherein a gain of the first channel signal is adjusted before combining with the first bass information signal.

3. The method as claimed in claim 1, wherein a gain of the low frequency signal is adjusted before combining with the first bass information signal.

4. The method as claimed in claim 1, wherein the first bass information signal comprises a low frequency effect signal.

5. The method as claimed in claim 1, further comprising selectively outputting or redirecting LFE to one or more speaker driven by other processing, wherein the speaker comprises a subwoofer and the full range speaker.

6. The method as claimed in claim 1, further comprising combining the LFE and a bass information signal generated by other processing unit when outputting to the subwoofer.

7. The method as claimed in claim 1, wherein the first bass information signal is low pass filtered before combining with the first channel signal.

8. An audio system with bass management, comprising:
a first processing unit high pass filtering a first channel signal to drive a first speaker and low pass filtering the first channel signal to generate a first low frequency signal if the first speaker is not a full range speaker, or combining a first bass information signal with the first channel signal to drive the first speaker if the first speaker is a full range speaker; and
a second processing unit selectively combining a second channel signal and the first low frequency signal to drive a second speaker when the second speaker is a full range speaker, optionally redirecting the first channel signal to the first processing unit as the first bass information if the first speaker is a full range speaker.

9. The system as claimed in claim 8, wherein the first channel signal is selected from the group consisting of left, right, center and surround channel signals.

10. The system as claimed in claim 8, wherein the first bass information signal comprises a low frequency effect signal.

11. The system as claimed in claim 8, wherein a gain of the first channel signal is adjusted before combining with the first bass information signal.

12. The system as claimed in claim 8, wherein the first bass information signal is low pass filtered before combining with the first channel signal.

13. A multi-speaker audio system, comprising:
a first processing unit for driving a first speaker, receiving a first audio channel signal comprising:
a first gain controller for adjusting the gain of the first audio channel signal;
a multiplexer for determining the processing path based on the type of the first speaker;
a low pass filter receiving the first audio channel signal for generating a first low frequency signal;
a high pass filter receiving and processing the first audio channel signal to drive the first speaker when the first speaker is a small speaker;
a summing module receiving the first audio channel signal and a low frequency signal from at least one other channel to drive the first speaker when the first speaker is a large speaker; and
a second processing unit for driving a second speaker, receiving a low frequency effect signal comprising:
a second gain controller for adjusting the gain of the low frequency effect signal;
a first multiplexer for determining whether the low frequency effect signal passes a low pass filter;
a second multiplexer for determining the processing path, wherein one processing path passes the signal directly to the second speaker or the first speaker when the first speaker is the large speaker and the second speaker does not exist; and
a summing module receiving and summing the signal from the second multiplexer and first low frequency signal to drive the second speaker.

14. The system as claimed in claim 13, further comprising a third gain controller for adjusting the gain of the first low frequency signal.
